(19) United States
(12) Patent Application Publication
(10) Pub. No.: US 2019/0371759 A1
(43) Pub. Date: Dec. 5, 2019

(54) PHYSICAL QUANTITY MEASUREMENT DEVICE AND METHOD FOR MANUFACTURING SAME, AND PHYSICAL QUANTITY MEASUREMENT ELEMENT

(71) Applicant: HITACHI AUTOMOTIVE SYSTEMS, LTD., Hitachinaka-shi, Ibaraki (JP)

(72) Inventors: Takuya AOYAGI, Ibaraki (JP); Mizuki IJUIN, Ibaraki (JP); Daisuke TERADA, Ibaraki (JP); Hiroshi ONUKI, Ibaraki (JP); Shigenobu KOMATSU, Ibaraki (JP); Takashi NAITOU, Tokyo (JP); Tatsuya MIYAKE, Tokyo (JP)

(73) Assignee: HITACHI AUTOMOTIVE SYSTEMS, LTD., Hitachinaka-shi, Ibaraki (JP)

(21) Appl. No.: 16/477,766

(22) PCT Filed: Jan. 24, 2018
(86) PCT No.: PCT/JP2018/002075

§ 371 Date: Jul. 12, 2019

(30) Foreign Application Priority Data
Mar. 10, 2017 (JP) 2017-045605

(51) Int. Cl. H01L 23/00; G01L 9/00

(52) U.S. Cl. CPC H01L 24/30; H01L 2224/8389; H01L 24/32; H01L 24/83; G01L 9/0042; H01L 2224/83203; H01L 2224/29083; H01L 2224/29372; H01L 2224/29339; H01L 2924/01052; H01L 2224/29147; H01L 2224/29124; H01L 2224/29166; H01L 2224/29155; H01L 2224/2918; H01L 2224/29149; H01L 2224/29184; H01L 2224/29171; H01L 2224/33505; H01L 2224/32245; H01L 2224/29288; H01L 24/29

(57) ABSTRACT

It is an object to provide a highly reliable physical-quantity measurement device which can relax thermal stress at a time of bonding and suppress creep or drift of a sensor output.

To attain the above-described object, a physical-quantity measurement device according to the present invention includes a semiconductor element, and a base board connected to the semiconductor element with a plurality of layers being interposed. In the plurality of layers, a stress relaxing layer including at least metal as a main ingredient and a glass layer including glass as a main ingredient are formed each in a layered form including one or more layers. At least one of the stress relaxing layer and the glass layer includes low-melting-point glass, and a softening point of the low-melting-point glass is equal to or lower than the highest heat temperature that the semiconductor element can resist.

### TECHNICAL FIELD

The present invention relates to a physical-quantity measurement device which measures a physical quantity such as a pressure, for example, a method for manufacturing the same, and a physical-quantity measurement element.

### BACKGROUND ART

A physical-quantity measurement device means a pressure sensor, a torque sensor, and the like which are mounted in a vehicle, for example, is formed by mounting of a semiconductor element made of silicon, and is used for measuring a fuel pressure of an engine, a hydraulic pressure of a brake, various kinds of gas pressures, and the like.

In a conventional pressure measurement device, it is general that a semiconductor element is mounted on a diaphragm made of metal. With regard to a material of such diaphragm, whereas a Fe—Ni-based alloy or the like having a coefficient of thermal expansion which is close to that of silicon is used in some cases, it is required to use a stainless-steel-based diaphragm from viewpoints of proof stress and corrosiveness.

However, stainless steel and a semiconductor element have respective coefficients of thermal expansion which are significantly different from each other, and thus high stress is caused in a bonding layer during a cooling process at a time of bonding. For this reason, it is desired that adhesion is achieved using solder, resin, or the like which can relax stress at a time of bonding on the one hand, but on the other hand, the foregoing materials are not desirable for a pressure measurement device because they creep, though suitable for bonding.

In order to solve the above-described problem, for example, PTL 1 discloses a method in which glass which is a brittle material is used as an adhesive agent and the glass is made multilayered, to reduce thermal stress at a time of bonding. Nonetheless, according to the method of PTL 1, since only a brittle material is used for a structure, thermal stress being applied at a time of bonding is unsatisfactorily relaxed. Accordingly, there arises a problem of drift of a sensor output particularly when an endurance test at a low temperature of −40° C. at which thermal stress becomes critical is conducted.

### CITATION LIST

### Patent Literature

PTL 1: WO 2015-098324 A

### SUMMARY OF INVENTION

### Technical Problem

In view of the foregoing situation, it is an object of the present invention to provide a highly reliable physical-quantity measurement device which can relax thermal stress at a time of bonding and suppress creep and drift of a sensor output.

### Solution to Problem

To attain the above-described object, a physical-quantity measurement device according to the present invention includes: a semiconductor element; and a base board connected to the semiconductor element with a plurality of layers being interposed, wherein in the plurality of layers, a stress relaxing layer including metal as a main ingredient and a glass layer including glass as a main ingredient are formed each in a layered form including one or more layers, and at least one of the stress relaxing layer and the glass layer includes low-melting-point glass, and a softening point of the low-melting-point glass is equal to or lower than the highest heat temperature that the semiconductor element can resist.

### Advantageous Effects of Invention

According to the present invention, it is possible to provide a highly reliable physical-quantity measurement device which can satisfactorily relax thermal stress at a time of bonding and can suppress creep and drift of a sensor output.

### BRIEF DESCRIPTION OF DRAWINGS

FIG. 1 is a schematic sectional view of a whole of a pressure measurement device according to one embodiment of the present invention.

FIG. 2 is a circuit diagram of a whole of a pressure measurement device according to one embodiment of the present invention.

FIG. 3 is a sectional view of a joint structure according to one embodiment of the present invention.

FIG. 4 is a sectional view of a joint structure according to one embodiment of the present invention.

FIG. 5 is a sectional view of a joint structure according to one embodiment of the present invention.

FIG. 6 is a sectional view of a joint structure according to one embodiment of the present invention.

FIG. 7 is a sectional view of a joint structure according to one embodiment of the present invention.

FIG. 8 shows an example of a DTA curve which is obtained by DTA measurement of a constituent of glass.

### DESCRIPTION OF EMBODIMENTS

Hereinbelow, embodiments of the present invention will be described in detail with reference to the drawings. The present invention does not limit a physical quantity to a specific physical quantity, and any physical quantity that can be detected using a semiconductor element can be handled. However, the following description will deal with a device which detects a pressure as one example of a physical quantity to be detected. Also, the present invention is not limited to description in the following examples, and the examples may be appropriately combined with each other. In the following examples, a diaphragm 14 made of metal is described as one example of a base board in which a semiconductor element is mounted.

### First Example

(Pressure Measurement Device)

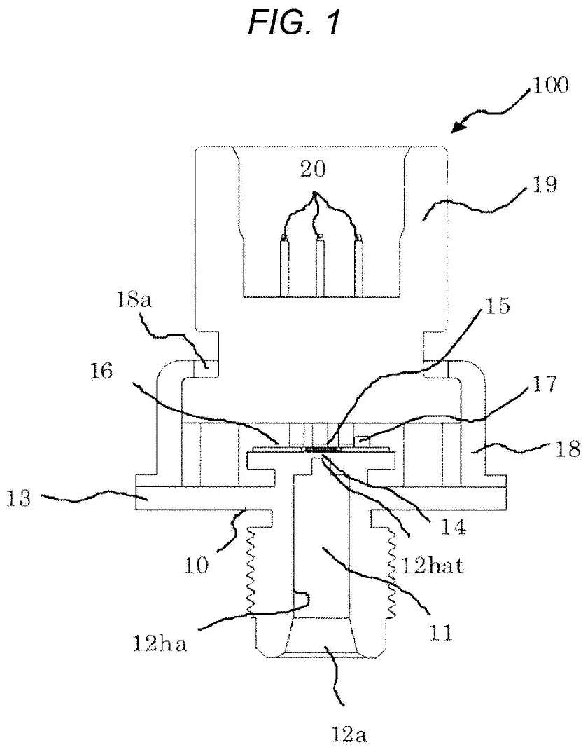

FIG. 1 is a conceptual view of a pressure measurement device 100.

The pressure measurement device 100 includes a metallic housing 10 in which a pressure port 11, a diaphragm 14, and a flange 13 are formed, a semiconductor element 15 which measures a pressure inside the pressure port 11, a substrate 16 which is electrically connected to the semiconductor element 15, a cover 18, and a connector 19 for electrical connection to the outside.

The pressure port 11 includes a pressure introduction unit 12ha in a shape of a hollow cylinder in which a pressure introduction tap 12a is formed at one of axial ends (on a lower side), and the flange 13 which has a cylindrical shape and is formed at the other of the axial ends of the pressure introduction unit 12ha (on an upper side). In a central portion of the flange 13, the diaphragm 14 which deforms due to a pressure so that a strain is caused is provided so as to stand erect.

The diaphragm 14 includes a pressure receiving surface which receives a pressure introduced through the pressure introduction tap 12a, and a sensor-mounted surface opposite to the pressure receiving surface.

In the pressure introduction unit 12ha of the pressure port 11, a tip end 12hat which is located close to the diaphragm 14 and faces the semiconductor element 15 has a rectangular shape, and the tip end 12hat is provided in such a manner that it continuously protrudes to a height which is a little small than heights of a central portion of the flange 13 and an upper surface of the diaphragm 14. The rectangular shape of the tip end 12hat causes a strain difference of (x direction−y direction) in the diaphragm 14.

The semiconductor element 15 is bonded to a substantially central portion of the sensor-mounted surface of the diaphragm 14. The semiconductor element 15 is formed as a semiconductor chip which includes one or more strain resistance bridges 30a to 30c each outputting an electric signal in accordance with deformation (strain) of the diaphragm 14 on a silicon chip.

In the substrate 16, an amplifier which amplifies each detection signal output from the semiconductor element 15, an A-to-D converter which converts an analog output signal of the amplifier into a digital signal, a digital-signal processing circuit which performs corrective calculation which will be later described, based on a digital signal provided from the amplifier, a memory in which various kinds of data are stored, a capacitor 17, and the like, are mounted.

In a blocking plate 18a which blocks the other axial end of the cover 18, a portion which is located in a substantially central position and has a predetermined diameter is cut out, and the connector 19 which is formed of resin or the like, for example, and outputs a detected pressure value provided by the pressure measurement device 100, to the outside, is inserted into the cut-out portion.

One end of the connector 19 is fixed to the cover 18 within the cover 18, and the other end of the connector 19 is exposed to the outside from the cover 18.

The connector 19 includes bar-shaped terminals 20 which are inserted by an insert molding method, for example. The terminals 20 include three terminals for power supply, for grounding, and for signal output, respectively, for example. One end of each of the terminals 20 is connected to the substrate 16 and the other end is connected to an external connector not shown in the drawings, so that the terminals 20 are electrically connected to an ECU or the like of an automobile via a wiring member.

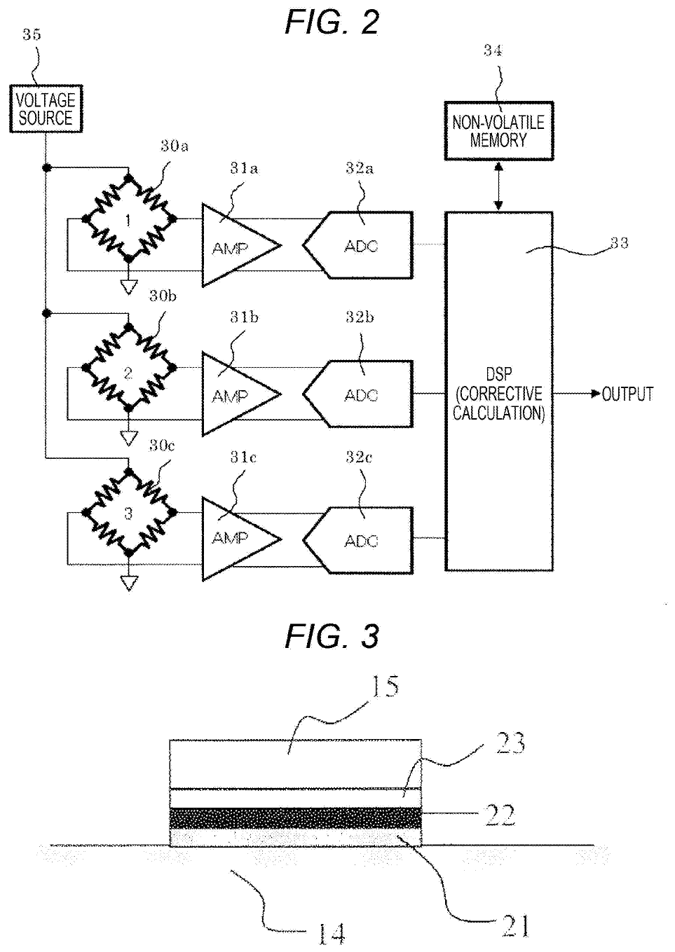

FIG. 2 is a circuit diagram of the plurality of strain resistance bridges of the semiconductor element 15 and circuit components mounted in the substrate 16.

The strain resistance bridges 30a to 30c are formed by bridging of resistance gages each of which is distorted along with deformation of the diaphragm 14 so that a resistance value thereof varies.

Output signals (bridge signals corresponding to pressures) of the strain resistance bridges 30a to 30c are amplified by amplifiers 31a to 31c, and amplified output signals are converted into digital signals by analog-to-digital (A-to-D) converters 32a to 32c.

A digital-signal processing circuit 33 performs arithmetic processing for correcting a pressure value which is detected by one strain resistance bridge, the strain resistance bridge 30a, for example, with the use of detected pressure values of the other strain resistance bridges 30b and 30c, based on output signals of the A-to-D converters 32a to 32c, and outputs a corrected pressure value as a detected value of the pressure measurement device.

The digital-signal processing circuit 33 performs not only processing for corrective calculation, but also processing for judging that an apparatus being measured or the semiconductor element 16 is degraded by comparison between respective detected pressure values of a plurality of strain resistance bridges or by comparison between a detected pressure value of a strain resistance bridge and a prescribed pressure value which is previously stored in a non-volatile memory 34, and outputting a fault signal at a time of judgment, or the other like processing.

It is noted that power supply from a voltage source 35 to the strain resistance bridges 30a to 30c and output of each signal from the digital-signal processing circuit 33 are achieved via the terminals 20 in FIGS. 1 and 2.

The non-volatile memory 34 may be mounted in a circuit chip which is different from a circuit chip in which the other circuit components are mounted. Also, a configuration in which the foregoing corrective calculation is performed by an analog circuit, in place of the digital-signal processing circuit 33, may be provided.

(Joint portion of semiconductor element and diaphragm) FIG. 3 is a sectional view of a joint structure of the semiconductor element 15 and the diaphragm 14 in the present example.

The diaphragm 14 and the semiconductor element 15 are bonded to each other with an insulating layer 21, a bonding layer 22, and a stress relaxing layer 23 being interposed.

A material of the diaphragm 14 is required to be resistant to corrosion and be highly resistant to strength in order to cope with a high pressure. For this reason, SUS630, SUS430, or the like is employed, for example.

In this regard, silicon (coefficient of thermal expansion: 37×10⁻⁷/° C.) is used as a material of the semiconductor element 15, and thus, faulty bonding is likely to occur due to a difference in a coefficient of thermal expansion between silicon and SUS630 (coefficient of thermal expansion: 113×10⁻/° C.) of the diaphragm 14 which is a member being bonded. Accordingly, the stress relaxing layer 23 is interposed in bonding those materials having different coefficients of thermal expansion, to each other, so that reliability and stability in bonding is improved. It is noted here that a coefficient of thermal expansion in the present invention means a value which is measured at temperatures in a range from 50 to 250° C.

It is preferable that the insulating layer 21, the bonding layer 22, and the stress relaxing layer 23 are formed of a lead-free material in view of environmental friendliness. A term “lead-free” referred to in the present invention acceptably means including a prohibited substance in a directive of Restriction of Hazardous Substances (RoHS: with effect of Jul. 1, 2006), within a range equal to or smaller than a specified value.

The bonding layer 22 includes low-melting-point glass. FIG. 8 shows a typical DTA curve of glass. As shown in FIG. 8, a second endothermic peak is defined as a softening point (Tₛ). Low-melting-point glass which is here referred to means glass having a softening point of 600° C. or lower. In order to bond a semiconductor element at a temperature equal to or lower than the highest heat temperature that a semiconductor element can resist, a softening point of glass should be equal to or lower than the highest heat temperature that a semiconductor element can resist. As an example of low-melting-point glass, glass which includes at least two kinds or more out of a vanadium element, silver element, and a tellurium element, in composition thereof, is cited. Also, in a case where silver is included in composition, a softening point of glass can be set at 300° C. or lower, so that bonding at a low temperature is feasible. Accordingly, reliability in bonding is further improved.

The insulating layer 21 is required to have an insulating property. This is because to have an insulating property can reduce a noise which is applied to the semiconductor element 15 by the diaphragm 14 when mounted in an automobile or the like. The term “insulating property” referred to in the present invention means having volume resistivity of 10¹⁰ Ωcm or higher.

With regard to the insulating layer 21, there is no specific requirement, and anything that has an insulating property including a general glass material or the like can be employed. Also, in a case where the insulating layer 21 is formed by heat treatment using a paste, crystallized glass may be employed. Also, there is no specific requirement regarding a thickness of the insulating layer 21, and a wide range of approximately 5 to 500 μm can be employed. However, it is particularly preferable that a thickness of the insulating layer 21 is 20 μm or more to 300 μm or less in relation to reliability and an output thereof as a sensor.

The stress relaxing layer 23 includes metal as a main ingredient. The term “main ingredient” which is here referred to, indicates a state in which 50% by volume or more is included. Metal included in the stress relaxing layer 23 is at least one kind selected from Ag, Cu, Al, Ti, Ni, Mo, Mn, W, and Cr. By using the above-cited metal for a stress relaxing layer, it is possible to provide a highly reliable physical-quantity measurement device.

While there is no specific limitation on a method for forming the stress relaxing layer 23, the stress relaxing layer 23 can be formed on a semiconductor element or a base board by a sputtering method, a plating method, a vapor deposition method, or the like. In a case where a single metallic layer is caused to function as a stress relaxing layer by a sputtering method or the like, it is preferable that a thickness of a stress relaxing layer is 0.05 μm or more to 10 μm or less in total. It is more preferable that a thickness is 1.5 μm or more to 5 μm or less. This is because to make a thickness much smaller cancels an effect of relaxing stress, and to make a thickness much larger allows creep to greatly affect at a high temperature.

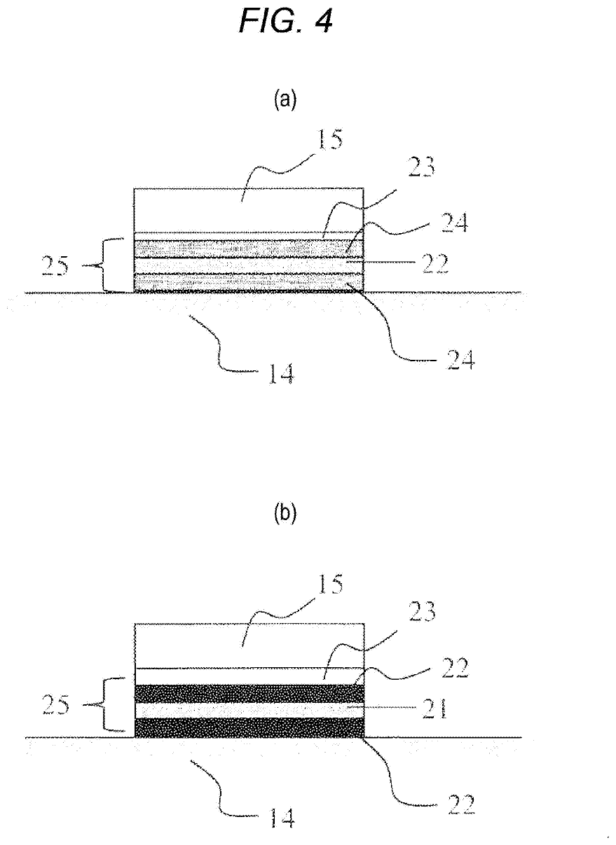

With regard to an order of the insulating layer 21, the bonding layer 22, and the stress relaxing layer 23 in FIG. 3, there is no specific requirement, and various combinations shown in FIGS. 3 to 7 can be considered as will be later described. As shown in those drawings, each of the insulating layer 21, the bonding layer 22, the stress relaxing layer 23 may include one or more layers. Also, there can be a case in which a layer like a stress-relaxing bonding layer 24 which has both functions of a bonding layer and a stress relaxing layer as shown in FIGS. 4(a), 6, and 7 is formed, for example. Therefore, there is no specific limitation on where the stress relaxing layer 23 is provided in a joint structure.

(Preparation of Glass G1)

While there is no specific limitation on a method for preparing glass which is used in a bonding-layer forming paste, it is possible to prepare such glass by putting a raw material in which oxide materials are compounded and mixed with each other, into a platinum crucible, heating it up to 800 to 1100° C. at a temperature-increase rate of 5 to 10° C./minute in an electric furnace, and holding it for several hours. It is preferable that a raw material is stirred while being held, in order to obtain uniform glass. When a crucible is taken out from an electric furnace, it is preferable to flow contents of the crucible onto a graphite mold or a stainless-steel plate which is previously heated to approximately 100 to 150° C., in order to prevent adsorption of moisture on a surface of glass.

In the present example, glass G1 was prepared under the following procedure. As a raw-material compound, one kilogram of mixed powder in which 45% by mass vanadium pentoxide, 30% by mass tellurium oxide, 15% by mass ferric oxide, and 10% by mass phosphorus pentoxide were compounded and mixed was put into a platinum crucible, was heated up to a heating temperature of 1000° C. at a temperature-increase rate of 5 to 10° C./min. (° C./minute), using an electric furnace, and was held for two hours. The mixed powder was stirred while being held in order to obtain uniform glass. Subsequently, the platinum crucible was taken out from the electric furnace, and contents of the platinum crucible were flowed onto a stainless-steel plate which was previously heated to 100° C., so that the glass G1 was obtained. Meanwhile, a softening point of the glass was 355° C.

(Preparation of a Bonding-Layer Forming Paste)

In order to manufacture the bonding layer 22, a bonding-layer forming paste was prepared. For the bonding-layer forming paste, the glass prepared in the above-described manner was ground using a jet mill until an average particle size (D50) of the glass became equal to approximately 3 μm, and thereafter, 30% by volume Zr₂ (WO₄)(PO₄)₂(ZWP) was added as a filler having the same size as the glass, i.e., a size of approximately 3 μm, to the glass. To the thus obtained mixture, ethyl cellulose and butyl carbitol acetate were added, as binder resin and a solvent, respectively, and were kneaded, so that a bonding-layer forming paste was prepared.

While there is no specific limitation on a solvent used for a bonding-layer forming paste, butyl carbitol acetate or α-terpineol can be used.

While there is no specific limitation on a binder used for a bonding-layer forming paste, ethyl cellulose or nitrocellulose can be used.

(Formation of Stress Relaxing Layer)

As a stress relaxing layer, an Al film was formed on a bonding surface of a semiconductor element (coefficient of thermal expansion: 37×10⁻⁷/° C.) which is a member being bonded, by a DC sputtering method. Thicknesses of the Al film at that time are shown in Table 1 (A3 to A12). At that time, Ti having a thickness of 250 nm was formed as an adhering layer for the A1 film, between the semiconductor element and the A1 film. Also, for comparison, two types of bonding surfaces of the semiconductor element, a non-processed surface (A1) and an oxidized surface (A2), were used.

(Manufacture and Evaluation of Pressure Measurement Device)

As members being bonded, a semiconductor element in which a stress relaxing layer having a thickness shown in Table 1 was formed, and a diaphragm made of SUS630 (coefficient of thermal expansion: 110×10⁻⁷/° C.) were used. As an insulating-layer forming paste, an SiO₂—Al₂O₃—BaO-based glass paste which is commercially available (manufactured by DuPont, coefficient of thermal expansion: 71×10⁻/° C.) was formed on an upper surface of the diaphragm. In the formation, after the insulating-layer forming paste was printed on the diaphragm using screen printing and was dried at 150° C. for 30 minutes, firing was carried out at 850° C. for 10 minutes, so that an insulating layer having a thickness of approximately 20 μm was formed. An upper surface of the insulating layer was coated with the bonding-layer forming paste prepared in the above-described manner also by screen printing, and was held at 400° C. for 30 minutes to be subjected to provisional firing, so that a bonding layer having a thickness of approximately 20 μm was formed. Thereafter, a silicon substrate in which a stress relaxing layer was formed was placed on an upper surface of the bonding layer, and a load was applied onto an upper surface of the silicon substrate. Then, a resultant matter was held at 400° C. for 10 minutes, so that a joint structure was manufactured. The following shear strength test and the following thermal shock test were conducted on the manufactured joint structure. In a shear strength test, adhering strength for bonding was evaluated. Results of evaluation were expressed in such a manner that samples each having shear strength which is equal to or higher than 20 MPa were marked with ∘, samples each having shear strength which is equal to or higher than 10 MPa and is lower than 20 Mpa were marked with Δ, and samples each having shear strength which is lower than 10 MPa were marked with x. A thermal shock test was conducted at temperatures in a range of −40° C. to 130° C., and reliability in bonding was evaluated. Results of evaluation were expressed in such a manner that samples in each of which a crack in a chip or peel did not occur after being subjected to 1000 cycles were marked with ∘, samples, 30% or smaller of which malfunctioned due to crack in a chip or peel were marked with Δ, and samples, more than 30% of which malfunctioned were marked with x. Those results are shown together in Table 1.

Also, the foregoing joint structure was adapted so as to function as a pressure sensor shown in FIG. 1. The following reliability test was conducted on the manufactured pressure sensor. The pressure sensor was let stand at −40° C. for 1000 hours, and a low-temperature drift characteristic of an output value of the sensor was evaluated. Results of evaluation were expressed in such a manner that samples in each of which a difference between an output value before the test and an output value after the test at 20° C. was smaller than 2% were marked with ∘, samples in each of which the foregoing difference was equal to or larger than 2% and was smaller than 5% were marked with Δ, and samples in each of which the foregoing difference was equal to or larger than 5%, or samples which could not be evaluated, were marked with x. Further, the sensor was let stand at 140° C. for 1000 hours, and a high-temperature drift characteristic of an output of a sensor was evaluated. Results of evaluation were expressed in such a manner that samples in each of which a difference between an output value before the test and an output value after the test at 20° C. was smaller than 2% were marked with ∘, samples in each of which the foregoing difference was equal to or larger than 2% and was smaller than 5% were marked with Δ, and samples in each of which the foregoing difference was equal to or larger than 5%, or samples which could not be evaluated, were marked with x. The above results are shown together in Table 1.

TABLE 1

| | Thickness of | Shear | Thermal | Low-temperature | High-temperature | | |
|---|---|---|---|---|---|---|---|
| Sample | metallized film | strength | shock | drift | drift | | |
| No. | (μm) (μm) | test | test | characteristic | characteristic | Judgement | |
| A1 | None | x | x | x | x | x | Comparative |
| | (unprocessed) | | | | | | example |
| A2 | None | x | x | x | x | x | Comparative |
| | (oxidized) | | | | | | example |
| A3 | 0.05 | ∘ | Δ | Δ | ∘ | Δ | Example |
| A4 | 0.1 | ∘ | Δ | Δ | ∘ | Δ | Example |
| A5 | 0.3 | ∘ | Δ | Δ | ∘ | Δ | Example |
| A6 | 0.5 | ∘ | Δ | Δ | ∘ | Δ | Example |
| A7 | 1.0 | ∘ | Δ | Δ | ∘ | Δ | Example |
| A8 | 1.5 | ∘ | ∘ | ∘ | ∘ | ∘ | Example |
| A9 | 2.0 | ∘ | ∘ | ∘ | ∘ | ∘ | Example |
| A10 | 2.5 | ∘ | ∘ | ∘ | ∘ | ∘ | Example |
| A11 | 5.0 | ∘ | ∘ | ∘ | ∘ | ∘ | Example |
| A12 | 10.0 | ∘ | ∘ | ∘ | Δ | Δ | Example |

Based on the above-shown results, in each of samples (A3 to A12) in which A1 was formed, reliability of a pressure sensor was improved, as compared to a case in which A1 serving as a stress relaxing layer was not formed on a bonding surface (A1, A2). At that time, regarding a film thickness for metallization, 0.05 μm to 10 μm was favorable. Particularly, in a case where a thickness was equal to 1.5 μm or more to 5 μm or less, much better results as to a characteristic of a pressure sensor were attained. Also, shear strength for bonding was improved as compared to comparative examples, and formation of a metallized film produced good results in view of not only relaxation of stress, but also adhesiveness.

### First Comparative Example

A commercially-available lead-based glass paste (which is manufacture by AGC, is used for bonding at 430° C., and has a coefficient of linear expansion of 72×10⁻⁷/° C.) was used as a bonding-layer forming paste. Members being bonded were held at 430° C. for 10 minutes using the foregoing glass paste, so that a joint structure was experimentally prepared. It is noted that conditions for experimental preparation were similar to those in the first example, except a bonding-layer forming paste. A joint structure which was experimentally prepared was adapted so as to function as a sensor in the same manner as in the first example. This revealed that an abnormal operation of a chip was caused in an initial stage in some samples. It can be considered that such abnormal operation depends on the highest heat temperature that a chip can resist. Then, it turned out that a temperature equal to or lower than 400° C. was preferable as a bonding temperature.

### Second Example

An example of the present invention will be described with reference to Table 2. It is noted that description of components similar to those in the first example will be omitted.

For a stress relaxing layer 23 in the present example, plural types of metallic thin films (B1 to B5) shown in Table 2 were formed by a sputtering method in the same manner as in the first example. With the other conditions being set in the same manner as in the first example, a sensor characteristic was evaluated. Results thereof were shown together in Table 2.

TABLE 2

| | | Shear | Thermal | Low-temperature | High-temperature | | |
|---|---|---|---|---|---|---|---|
| Sample | Kind of metal | strength | shock | drift | drift | | |
| No. | (Thickness: μm) | test | test | characteristic | characteristic | Judgement | |
| B1 | Cr (0.01)/Ag (2) | ∘ | ∘ | ∘ | ∘ | ∘ | Example |
| B2 | Ti (0.02)/Cu (2)/A1 (0.05) | ∘ | ∘ | ∘ | ∘ | ∘ | Example |
| B3 | Mo (2)/A1 (0.05) | ∘ | ∘ | ∘ | ∘ | ∘ | Example |
| B4 | Cr (0.01)/W(2)/A1 (0.05) | ∘ | ∘ | ∘ | ∘ | ∘ | Example |
| B5 | Cr (0.01)/Mn (2)/A1 (0.05) | ∘ | ∘ | ∘ | ∘ | ∘ | Example |

Based on the above-shown results, a type of a stress relaxing layer was not limited to a type of Al, and each of metallic thin films of Ag, Cu, Mo, W, Mn, and Cr shown in Table 2 produced the same effect. Also, in order to improve adhesiveness to semiconductor element, a multilayer configuration may be provided, and Cr, Ti, or the like can be used for the purpose of improving adhesiveness.

### Third Example

A fourth example of the present invention will be described with reference to FIG. 4(a). It is noted that description of the same components as those in the first example will be omitted.

As shown in FIG. 4(a), a bonding material 25 in which a stress-relaxing bonding layer 24 which combines functions of the bonding layer 22 and the stress relaxing layer 23, and an insulating layer 21 are previously formed integrally with each other, is included. Then, the bonding material 25 is placed between a semiconductor element 15 and a diaphragm 14, and bonding is achieved. One surface of the semiconductor element 15 is metallized in the manner described above in the first example. A resultant metallic film is responsible for bonding the semiconductor element 15 and the bonding material 25.

The stress-relaxing bonding layer 24 includes metal and low-melting-point glass. Regarding low-melting-point glass, evaluation was made using glass G1 and glass G2 which will be later described. Also, regarding metal, evaluation was made using fillers shown in FIG. 3. At that time, metal included in the stress-relaxing bonding layer 24 is required to continuously pass (percolate) through a bonding layer. When expressed in terms of a content by volume, a content of the metal is 50% or more to 90% or less. This is because non-percolation does not produce an effect of relaxing stress while to include 90% by volume or more allows creep to greatly affect at a high temperature. C1 to C5 and C8 shown in Table 3 are samples of the stress-relaxing bonding layer 24.

(Method for Manufacturing a Bonding Material)

A method for manufacturing the bonding material 25 will be described.

First, after one of surfaces of an insulating base member is coated with a bonding-layer forming paste which forms one of stress-relaxing bonding layers 24 and is dried, the other of the surfaces of the insulating base member 22 is coated with a bonding-layer forming paste which forms the other of the stress-relaxing bonding layers 24 and is dried.

Thereafter, a process of removing a binder and a process of provisionally firing a bonding layer are performed by one operation. Further, a matter which has been provisionally fired is cut into pieces each in a predetermined size by a dicing method or the like, so that the bonding material 25 can be formed.

For the insulating base member, a glass plate (thickness: 145 μm, coefficient of linear expansion: 72×10⁻⁷/° C.) is used. Both of an upper surface and a lower surface of the glass plate are coated with a bonding-layer forming paste by screen printing, and are dried at 150° C. for 30 minutes. Subsequently, provisional firing is carried out, so that the bonding material 25 is obtained. Then, provisional firing was carried out at 270° C. for 30 minutes.

(Preparation of Glass G2)

The glass G2 was prepared under the same procedures as those in the first example. As a raw-material compound, one kilogram of mixed powder in which 20.5% by mass vanadium pentoxide, 33% by mass silver oxide, 39% by mass tellurium oxide, 5% by mass tungsten oxide, and 2.5% by mass lanthanum oxide were compounded and mixed, was put into a platinum crucible, was heated up to a heating temperature of 800° C. at a temperature-increase rate of 5 to 10° C./min. (° C./minute), using an electric furnace, and was held for two hours. The mixed powder was stirred while being held in order to obtain uniform glass. Subsequently, the platinum crucible was taken out from the electric furnace, and contents of the platinum crucible were flowed onto a stainless-steel plate which was previously heated to 100° C., so that the glass G2 was obtained. Meanwhile, a softening point of the glass was 245° C.

(Preparation of a Bonding-Layer Forming Paste)

For a bonding-layer forming paste, the glass prepared in the above-described manner was ground using a jet mill until an average particle size (D50) of the glass became equal to approximately 3 μm, and thereafter, Ag- and Al-powder having a size of approximately 1.5 μm to 3 μm was added to the glass in proportions shown in FIG. 3. To the resultant mixture, α-terpineol, or butyl carbitol acetate like that in the first example, was added and kneaded, so that a bonding-layer forming paste was prepared.

(Manufacture and Evaluation of Pressure Measurement Device)

As members being bonded, a semiconductor element and a diaphragm made of SUS630 were used in the same manner as in the first example. At that time, a sample A7 shown in Table 1 was used as a semiconductor element used for evaluation. The bonding material 25 manufactured in the above-described manner was placed between the semiconductor element and the diaphragm, and a load was applied onto an upper surface of the semiconductor element. Then, a resultant matter was heated, so that a joint structure was manufactured. At that time, the joint structure was held at 300° C. for 30 minutes. A shear strength test and a thermal shock test were conducted on the manufactured joint structure in the same manner as in the first example. Also, the joint structure was adapted so as to function as a pressure sensor in the same manner as in the first example, and a drift characteristic of an output value of a sensor at each of a low temperature and a high temperature was evaluated. Results thereof are shown together in Table 3.

TABLE 3

| | | | | Mixture | | | | Low- | High- | | |
|---|---|---|---|---|---|---|---|---|---|---|---|
| | | | | proportion | | Shear | Thermal | temperature | temperature | | |
| Sample | | Kind | | (volume %) | | strength | shock | drift | drift | | |
| No. | | Filler | Glass | Filler | Glass | test | test | characteristic | characteristic | Judgement | |
| C1 | Upper surface | Ag | G2 | 50 | 50 | ∘ | ∘ | ∘ | ∘ | ∘ | Example |
| | Lower surface | Ag | G2 | 50 | 50 | | | | | | |
| C2 | Upper surface | Ag | G2 | 50 | 50 | ∘ | ∘ | ∘ | ∘ | ∘ | Example |
| | Lower surface | Ag | G2 | 70 | 30 | | | | | | |
| C3 | Upper surface | Ag | G2 | 70 | 30 | ∘ | ∘ | ∘ | ∘ | ∘ | Example |
| | Lower surface | Ag | G2 | 70 | 30 | | | | | | |
| C4 | Upper surface | Ag | G2 | 50 | 50 | Δ | ∘ | ∘ | ∘ | Δ | Example |
| | Lower surface | Ag | G2 | 80 | 20 | | | | | | |
| C5 | Upper surface | Ag | G2 | 50 | 50 | Δ | ∘ | ∘ | ∘ | Δ | Example |
| | Lower surface | Ag | G2 | 90 | 10 | | | | | | |
| C6 | Upper surface | Ag | G2 | 50 | 50 | x | ∘ | ∘ | Δ | x | Comparative |
| | Lower surface | Ag | G2 | 95 | 5 | | | | | | example |
| C7 | Upper surface | Ag | G2 | 30 | 70 | x | x | x | x | x | Comparative |
| | Lower surface | Ag | G2 | 30 | 70 | | | | | | example |
| C8 | Upper surface | A1 | G2 | 50 | 50 | ∘ | ∘ | ∘ | ∘ | ∘ | Example |
| | Lower surface | A1 | G2 | 50 | 50 | | | | | | |

Based on the above-shown results, also in a case where the joint structure shown in FIG. 4(a) was used, a highly reliable physical-quantity measurement device could be manufactured. In other words, a stress relaxing layer can be formed also by methods other than a sputtering method, and could be formed using a paste including metallic particles and glass.

In the present example, since two stress-relaxing layers are provided as seen in samples C1 to C5 and C8, reliability can be further improved as compared to a case in which one stress relaxing layer is provided. Particularly regarding a thermal shock test or the like, while reliability may be unsatisfactory with only one stress relaxing layer, satisfactory reliability can be attained by provision of two stress relaxing layers, so that flexibility in selecting a material is improved. Also, a bonding layer and a stress relaxing layer can be implemented in one layer, which contributes to miniaturization.

In the present example, a percentage by volume of metallic particles (filler) was set to 50% or more to 90% or less as shown in Table 3, so that a bonding layer was provided with a function of a stress relaxing layer. It is more preferable that a percentage by volume of metallic particles is 50% or more to 70% or less, and this made it possible to manufacture a more highly reliable sensor.

### Fourth Example

A fourth example will be described with reference to FIG. 4(b). It is noted that description of the same components as those in the third example will be omitted.

A difference from the third example lies in that the stress-relaxing bonding layer 24 is replaced with a bonding layer 22.

Whereas a method for manufacturing a bonding material is similar to that of the third example, provisional firing was carried out at 400° C. for 30 minutes and ZWP powder was used as a filler member of a bonding-layer forming paste in the same manner as in the first example.

(Preparation of glass G3)

Glass G3 was prepared under the same procedures as those in the first example. As a raw-material compound, one kilogram of mixed powder in which 38% by mass vanadium pentoxide, 30% by mass tellurium oxide, 5.8% by mass phosphorus oxide, 10% by mass tungsten oxide, 11.2% by mass barium oxide, and 5% by mass potassium oxide were compounded and mixed, was put into a platinum crucible, was heated up to a heating temperature of 1100° C. at a temperature-increase rate of 5 to 10° C./min. (° C./minute), using an electric furnace, and was held for two hours. The mixed powder was stirred while being held in order to obtain uniform glass. Subsequently, the platinum crucible was taken out from the electric furnace, and contents of the platinum crucible were flowed onto a stainless-steel plate which was previously heated to 100° C., so that the glass G3 was obtained. Meanwhile, a softening point of the glass was 336° C.

With regard to manufacture of a pressure measurement device, a sample A8 was used as a semiconductor element used for evaluation. Also, for manufacture of a joint structure, members being bonded were heated at 400° C. and held for 10 minutes. A shear strength test and a thermal shock test were conducted on the manufactured joint structure in the same manner as in the first example. Also, the joint structure was adapted so as to function as a pressure sensor in the same manner as in the first example, and a drift characteristic of an output value of a sensor at each of a low temperature and a high temperature was evaluated. Results thereof are shown together in Table 4.

| | | | | Mixture proportion | | Shear | Thermal | Low-temperature | High-temperature | | |
|---|---|---|---|---|---|---|---|---|---|---|---|
| | | Kind | | (volume %) | | strength | shock | drift | drift | | |
| Sample No. | | Filler | Glass | Filler | Glass | test | test | characteristic | characteristic | Judgement | |
| D1 | Upper | ZWP | G1 | 40 | 60 | ∘ | ∘ | ∘ | ∘ | ∘ | Example |
| | surface | | | | | | | | | | |
| | Lower | ZWP | G3 | 30 | 70 | | | | | | |
| | surface | | | | | | | | | | |
| D2 | Upper | ZWP | G1 | 35 | 65 | ∘ | ∘ | ∘ | ∘ | ∘ | Example |
| | surface | | | | | | | | | | |
| | Lower | ZWP | G3 | 23 | 77 | | | | | | |
| | surface | | | | | | | | | | |
| D3 | Upper | ZWP | G1 | 30 | 70 | ∘ | ∘ | ∘ | ∘ | ∘ | Example |
| | surface | | | | | | | | | | |
| | Lower | ZWP | G3 | 30 | 70 | | | | | | |
| | surface | | | | | | | | | | |
| D4 | Upper | ZWP | G1 | 25 | 75 | ∘ | ∘ | ∘ | ∘ | ∘ | Example |
| | surface | | | | | | | | | | |
| | Lower | ZWP | G3 | 30 | 70 | | | | | | |
| | surface | | | | | | | | | | |
| D5 | Upper | ZWP | G1 | 40 | 60 | ∘ | ∘ | ∘ | ∘ | ∘ | Example |
| | surface | | | | | | | | | | |
| | Lower | ZWP | G3 | 35 | 65 | | | | | | |
| | surface | | | | | | | | | | |

As a result, each of samples was judged to be ∘ regarding all of a shear strength test, a thermal shock test, a low-temperature drift characteristic, and a high-temperature drift characteristic.

### Fifth Example

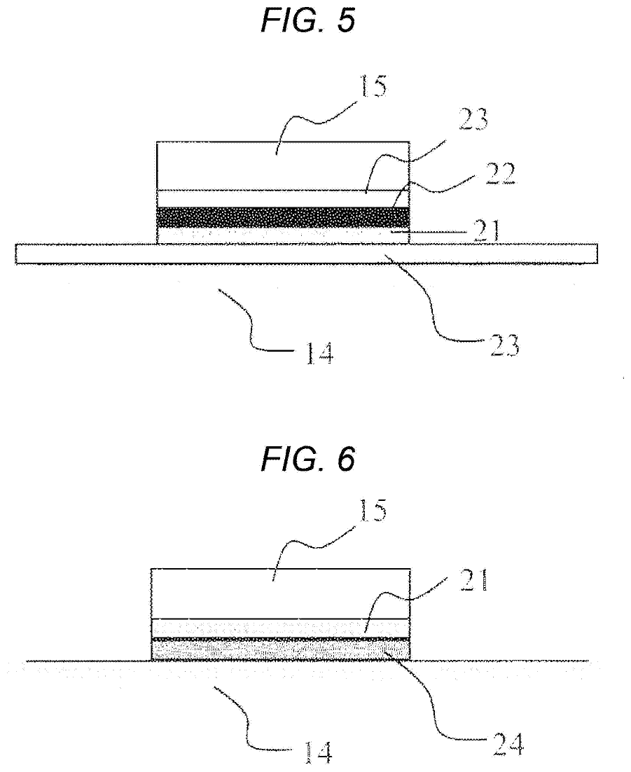

A fifth example will be described with reference to FIG. 5. It is noted that description of the same components as those in the first example will be omitted.

In the present example, Ni plating provided on a bonding surface of SUS630 is added to a configuration according to the first example. Ni plating functions as a stress relaxing layer 23. A thickness of Ni plating is set to 2 μm.

A sample A7 in the first example was used. Under the same conditions as those in the first example in all the other respects, a joint structure was formed. A shear strength test and a thermal shock test were conducted on the manufactured joint structure in the same manner as in the first example. Also, the joint structure was adapted so as to function as a pressure sensor in the same manner as in the first example, and a drift characteristic of an output value of a sensor at each of a low temperature and a high temperature was evaluated.

As a result, each of samples was judged to be ∘ regarding all of a shear strength test, a thermal shock test, a low-temperature drift characteristic, and a high-temperature drift characteristic. Therefore, it was confirmed that an effect of relaxing stress could be produced even in a case where a plating method was used.

### Sixth Example

A sixth example will be described with reference to FIG. 6. It is noted that description of the same components as those in the first example will be omitted.

Differences from the first example lie in that a stress relaxing layer 23 is not formed between a semiconductor element 15 and an insulating layer 21, and that the semiconductor element 15 and the insulating layer 21 are anodically bonded to each other using glass for anodic bonding (PYREX (registered trademark), having a thickness of 300 μm) for the insulating layer 21.

Anodic bonding is achieved under conditions that the semiconductor element 15 and the insulating layer 21 are held at a temperature of 350° C. and a voltage of 500 V for 60 minutes. As members being bonded, the semiconductor element manufactured in the above-described manner and a diaphragm made of SUS 630 were used. An upper surface of the diaphragm was coated with the paste used for C1 to C5 and C8 in the third example and dried at 150° C. for 30 minutes, and thereafter, provisional firing was carried out at 270° C. for 30 minutes, so that a stress-relaxing bonding layer 24 having a thickness of approximately 20 μm was formed. A shear strength test and a thermal shock test were conducted on the manufactured joint structure in the same manner as in the first example. Also, the joint structure was adapted so as to function as a pressure sensor in the same manner as in the first example, and a drift characteristic of an output value of a sensor at each of a low temperature and a high temperature was evaluated.

As a result, each of samples was judged to be ∘ regarding all of a shear strength test, a thermal shock test, a low-temperature drift characteristic, and a high-temperature drift characteristic. Therefore, it was confirmed that to incorporate a stress relaxing layer and an adhering layer in a single layer as shown in FIG. 6 was allowable.

### Seventh Example

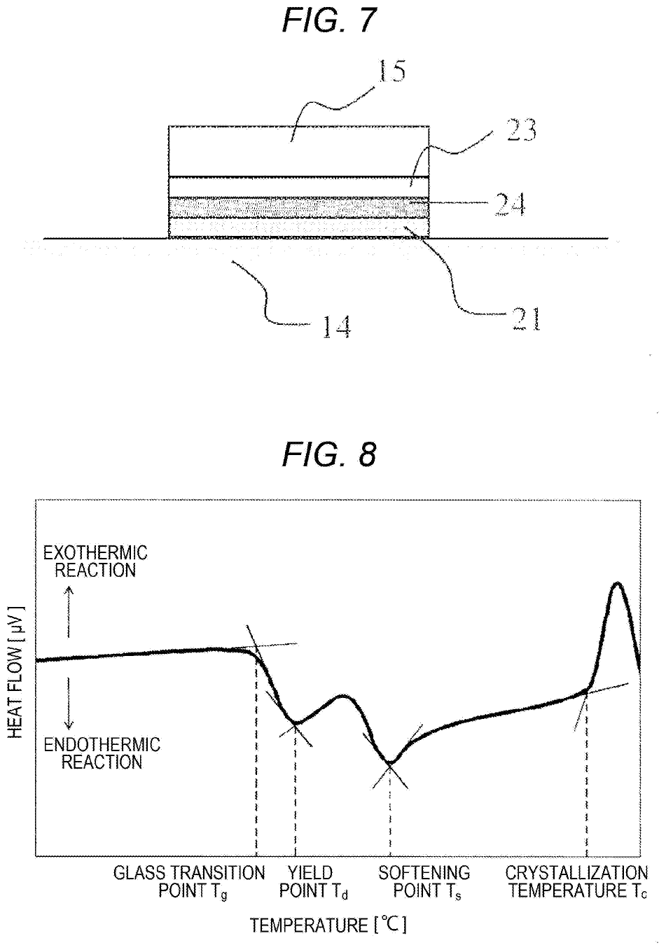

A seventh example will be described with reference to FIG. 7. It is noted that description of the same components as those in the first example will be omitted.

In settings of the first example, the paste used for C1 to C5 and C8 in the third example was used as a bonding-layer forming paste. At that time, a sample A7 in the first example was used as a configuration on a bonding-surface side of a semiconductor element. An insulating layer was formed in the same manner as in the first example, and only a bonding layer was provisionally fired at 270° C. for 30 minutes in the same manner as in the third example. Then, the semiconductor element was placed on the insulating layer, and heated at 300° C. for 30 minutes, so that bonding was achieved. A shear strength test and a thermal shock test were conducted on the manufactured joint structure in the same manner as in the first example. Also, the joint structure was adapted so as to function as a pressure sensor in the same manner as in the first example, and a drift characteristic of an output value of a sensor at each of a low temperature and a high temperature was evaluated.

As a result, each of samples was judged to be ∘ regarding all of a shear strength test, a thermal shock test, a low-temperature drift characteristic, and a high-temperature drift characteristic.

### REFERENCE SIGNS LIST

10 metallic housing
11 pressure port
12 pressure introduction unit
12a pressure introduction tap
12ha pressure introduction hole
12hat tip end
13 flange
14 diaphragm
15 semiconductor element
16 substrate
17 capacitor
18 cover
18a blocking plate
19 connector
20 terminal
21 insulating layer
22 bonding layer
23 stress relaxing layer
24 stress-relaxing bonding layer
25 bonding material
30a to 30c strain resistance bridge
31a to 31c amplifier
32a to 32c A-to-D converter
33 digital-signal processing circuit
34 non-volatile memory
35 voltage source
100 pressure measurement device

1. A physical-quantity measurement device comprising:
a semiconductor element; and
a base board connected to the semiconductor element with a plurality of layers being interposed, wherein
the plurality of layers include:
a stress relaxing layer including metal as a main ingredient;
an insulating layer; and
a bonding layer including low-melting-point glass that has a softening point equal to or lower than the highest heat temperature that the semiconductor element resists.

2. A physical-quantity measurement device comprising:
a semiconductor element; and
a base board connected to the semiconductor element with a plurality of layers being interposed, wherein
the plurality of layers include:
a stress-relaxing bonding layer in which a content by volume of metal is 50% to 90%, the stress-relaxing bonding layer including low-melting-point glass that has a softening point equal to or lower than the highest heat temperature that the semiconductor element resist; and
an insulating layer.

3. The physical-quantity measurement device according to claim 1, wherein
the stress relaxing layer is placed between the semiconductor element and the insulating layer, and/or between the insulating layer and the base board.

4. The physical-quantity measurement device according to claim 1, wherein
the stress-relaxing bonding layer is placed between the semiconductor element and the insulating layer, and/or between the insulating layer and the base board.

5. The physical-quantity measurement device according to claim 1, wherein
the metal includes at least one kind selected from Ag, Cu, Al, Ti, Ni, Mo, Mn, W, and Cr.

6. The physical-quantity measurement device according to claim 1, wherein
the low-melting-point glass includes at least two kinds or more out of a vanadium element, a silver element, and a tellurium element.

7. The physical-quantity measurement device according to claim 1, wherein
the stress relaxing layer is a sputtered layer or a plating layer.

8. The physical-quantity measurement device according to claim 1, wherein
a thickness of the stress relaxing layer is 0.05 μm or more to 10 μm or less in total.

9. The physical-quantity measurement device according to claim 8, wherein
the thickness of the stress relaxing layer is 1.5 μm or more to 5 μm or less in total.

10. The physical-quantity measurement device according to claim 2, wherein
a thickness of the stress-relaxing bonding layer is 0.05 μm or more to 10 μm or less in total.

11. The physical-quantity measurement device according to claim 10, wherein
the thickness of the stress-relaxing bonding layer is 1.5 μm or more to 5 μm or less in total.

12. The physical-quantity measurement device according to claim 2, wherein
the content by volume of the metal in the stress-relaxing bonding layer is 50% to 70%.

13. A method for manufacturing a physical-quantity measurement device, comprising the steps of:
forming a bonding-layer forming paste by mixing a metallic filler with low-melting-point glass in such a manner that a content by volume of the metallic filler is equal to or larger than 50%;
forming a bonding material by coating one of surfaces of a glass substrate with the bonding-layer forming paste and carrying out heat treatment;
placing the bonding material between a semiconductor element and a base board; and
bonding the semiconductor element and the base board by heating the semiconductor element and the base board at a heating temperature that is equal to or higher than a softening point and is equal to or lower than the highest heat temperature that the semiconductor element resist.

14. The method for manufacturing a physical-quantity measurement device according to claim 13, wherein
the heating temperature is equal to or lower than 300° C.
